(19) United States
(12) Patent Application Publication
(10) Pub. No.: US 2007/0217148 A1
(43) Pub. Date: Sep. 20, 2007

(54) POWER SUPPLY COOLING

(75) Inventors: Steffen Omnitz, March (DE); Stefan Schirmaier, Freiburg (DE); Markus Winterhalter, Bad Krozingen (DE); Peter Wiedemuth, Herbolzheim (DE)

Correspondence Address: FISH & RICHARDSON PC, P.O. BOX 1022, MINNEAPOLIS, MN, 55440-1022, US

(73) Assignee: HUETTINGER Elektronik GmbH + Co. KG, Freiburg (DE)

(21) Appl. No.: 11/530,242

(22) Filed: Sep. 8, 2006

Related U.S. Application Data
(63) Continuation of application No. PCT/EP05/02068, filed on Feb. 26, 2005.

(30) Foreign Application Priority Data
Mar. 11, 2004 (DE) 10 2004 012026.9

(51) Int. Cl. H05K 7/20

(52) U.S. Cl. 361/690

(57) ABSTRACT

A cooling device is provided for an electronic unit. In some implementations, the cooling device includes a cooling body, arranged in an essentially airtight sealed housing of the electronic unit, through which a cooling medium may flow. Heat generating elements, for example electronic components, are mounted on the cooling device so as to release the heat to the cooling body by contact transmission. Additional heat exchange means for cooling the air enclosed in the housing are connected to the cooling body with a thermal conducting connection and arranged on said cooling body. Such a cooling device can be produced with a compact construction with effective heat extraction.

### RELATED APPLICATIONS

This application is a continuation of, and claims priority under 35 U.S.C. §120 to PCT/EP2005/002068, filed on Feb. 26, 2005, and designating the U.S., and claims priority under 35 U.S.C. §119 from German application DE 10 2004 012026.9, filed Mar. 11, 2004. Both of these priority applications are hereby incorporated by reference in their entirety.

### TECHNICAL FIELD

This invention relates to a cooling device for an electrical unit, such as a power supply device.

### BACKGROUND

Housings of voltage converters (power supply devices), e.g. for plasma excitation, often require air-tight sealing, since these devices are often used in cleanrooms. Particles contained in the housing after assembly must be prevented from getting into the cleanrooms. For this reason, fans generating an air exchange between the housing and the surroundings are not suited for cooling. Similar constraints exist for devices that are used in dirty surroundings, where surrounding air must be prevented from getting into the housing.

The heat generated by components disposed in the housing is conventionally guided out of the housing through liquid coolant systems. The liquid coolant generally flows through a cooling body which is disposed in the housing. Components that heat up during operation are thermally coupled to this cooling body. The components which cannot be coupled to the cooling body or only to an insufficient degree, are generally cooled by the surrounding air which cannot escape from the housing. Heat is accumulated that heats the inside of the device. In order to prevent overheating of the device and the components, the air must be cooled, which is frequently effected using separate heat exchangers having a separate liquid coolant circuit.

DE 195 24 115 C2 discloses a cooling system which discharges thermal energy from the air in an enclosed system to a coolant circuit. Air that is heated at the electronic components disposed in a housing is thereby cooled in an intermediate channel. The intermediate channel discharges the heat to the atmosphere via a second air circulation. A liquid coolant circuit is additionally provided for cooling the power converters disposed in the housing, the liquid coolant of which is cooled by a cooler using atmospheric air.

### SUMMARY

The present disclosure concerns a cooling device for an electrical unit, in particular a power supply device. The cooling device includes a cooling body which is disposed in a housing of the, electrical device, which is sealed in an air-tight or at least substantially air-tight fashion, wherein a coolant may flow through the cooling body. Heat generating devices, in particular electronic components, are mounted to the cooling body, which release heat to the cooling body via contact transmission.

A substantially air-tight sealed housing defines a housing which is ideally air tight but has inadvertent leakages or small gaps through which small amounts of air can enter or escape. In any event, there is no deliberate supply of cooling air to this housing, and no large amounts of heated air are discharged from the housing.

This object is achieved by a cooling device of the above-mentioned type, wherein additional heat exchanging means are disposed on the cooling body, which are connected thereto in a heat conducting fashion, to cool the air in the housing.

A cooling device of this type realizes a compact design of a combination of a cooling body, which may be designed as a water cooling plate for cooling directly mounted components, and a heat exchanger for cooling the air inside the device. A cooling device of this type obviates the need for an additional air/water heat exchanger to cool the air in the housing. Additional water connections can be omitted which reduces the risk of leakages. The device can be adjusted to the thermal requirements and mechanical conditions, in particular, of compact devices in a highly flexible manner. Suitable construction of the heat exchanging means permits simple and inexpensive realization of three-dimensional designs. The geometry of the heat exchanging means can be selected in accordance with the specifications of the application. No separate coolant circuit is required to cool the heat exchanging means. The cooling body and the heat exchanging means may be realized in one component, thereby saving space.

With particular preference, a fan is disposed in the housing to circulate the heated air and ensure good circulation of the heated air around the heat exchanging means. The air inside the housing is thereby cooled more effectively.

The heat exchanging means may comprise a heat exchanger, which may for example comprise several heat exchanging elements. The heat exchanging elements may advantageously be formed as lamellae. This maximizes the heat exchanging surface for receiving heat from the air inside the device.

With particular preference, the cooling body is designed as a cooling plate with heat exchanging means projecting therefrom. This ensures compact construction. Disposing the heat-generating, electric components on a plate-like cooling body saves a lot of space.

In an advantageous embodiment of the invention, the heat exchanging means may be disposed on one side of the cooling body and the heat generating means may be disposed on the opposite side of the cooling body. The back side of the cooling body without components can thereby be almost completely equipped with heat exchanging means for cooling the air in the housing. This means that, on one side of the cooling body, heat is taken up from the components and immediately discharged to the liquid coolant, and on the opposite side thereof, heat is taken up from the air surrounding the cooling body via the heat exchanging means, and discharged to the coolant.

The function of the cooling device can be further improved, in some implementations, by disposing the heat exchanging means on two, in particular, opposite sides of the cooling body. In this fashion, almost any free space on the cooling body, i.e. any point on the cooling body that is not covered by components, can be provided with heat exchanging means, thereby withdrawing a maximum amount of heat from the air in the housing. Due to the arrangement on two opposing sides, the cooling body may be formed as a plate, thereby realizing an overall relatively flat configuration.

In one advantageous design of the invention, the heat exchanging means may be disposed between heat generating means. Heat may thereby be discharged directly from the immediate surroundings of the heat generating means.

With particular preference, a coolant channel is formed in the cooling body, which extends along mounting positions of heat generating means. The heat can therefore be discharged directly at the heat generating means which improves the cooling effect. The coolant channel may, in particular, be disposed and guided in the cooling body in dependence on the specifications of the application. The coolant channel is preferably guided past the components that produce the maximum amount of heat.

In one embodiment of the invention, heat exchanging means having different heights are provided. This influences the air flow in the housing and optimizes the heat transfer from the air into the heat exchanging means and thereby into the cooling body. The heat exchanging means may also have different heights along their extension, i.e. project from the cooling body by different lengths.

In one advantageous embodiment, the lamellar heat exchanging means are soldered in heat exchanging grooves of the cooling body. Soldering of the heat exchanging means in heat exchanging grooves of the cooling body provides a large-surface connection between the heat exchanging means and the cooling body. This ensures good heat transfer from the heat exchanging means to the cooling body.

When several heat exchanging means are disposed parallel to each other, air can flow between the heat exchanging means and a large amount of heat from the air can be transferred into the heat exchanging means.

The cooling body and/or the heat exchanging means are preferably made from copper or a higher-grade metal to ensure good heat conduction. In a particularly simple manner, the heat exchanging means and the cooling body may moreover be soldered to each other. In particular, the region defining the coolant channel should be made from copper or a higher-grade metal to prevent corrosion due to the passing coolant. The use of low-order metals would result in electrochemical potentials, causing corrosion in the entire coolant circuit, i.e. not only in the region of the coolant channel.

The disclosure also features a method for producing a cooling body comprising the following steps:

a. generating a coolant channel groove in the cooling body;

b. forming a coolant channel by closing the coolant channel groove with a cover part;

c. arranging heat exchanging means on the cooling body.

A coolant may circulate or flow in the coolant channel to discharge heat from the cooling body. The heat exchanging means are disposed on the cooling body to transfer heat from the surrounding air into the cooling body and thereby to the coolant. The coolant channel groove can be produced by milling a coolant channel groove into a cooling body. The shape of the cover part may substantially correspond to the shape or progression of the coolant channel groove. The coolant channel groove may be milled or produced in a different fashion.

In a preferred method variant, the heat exchanging means are arranged by providing several heat exchanging grooves in the cooling body and inserting the heat exchanging means into the heat exchanging grooves. This advantageously increases the mounting stability of the heat exchanging means on the cooling body, and realizes a large-surface connection between the heat exchanging means and the cooling body. This generally cannot be achieved by disposing heat exchanging means, which are e.g. formed as lamellas, with a narrow side thereof on the cooling body. Moreover, connection between the heat exchanging means and the cooling body is facilitated, e.g., through soldering.

In a preferred method variant, the cover part may be soldered to the cooling body at a first soldering temperature, e.g. in a range between 270° and 350° C., in particular between 290 and 307° C., and the heat exchanging means may be soldered to the cooling body at a second, lower soldering temperature, e.g. less than or equal to 230° C., in particular less than or equal to 200° C. This ensures that the first solder connection will not become detached when the heat exchanging means are soldered. The soldering temperatures are preferably selected to meet this condition. Depending on the materials to be soldered and the soldering aids used, the soldering temperatures may also be outside of the above-stated ranges. The use of solder connections is advantageous in that they provide good heat transfer between the soldered parts.

With particular preference, soldering is effected using induction heating. This method provides fast heat input into the material and very uniform heat distribution irrespective of the geometry of the cooling body, in particular, when an inductor with optimum geometrical shape is used. This also realizes energy-saving heat input with high efficiency and exactly adjustable temperature. The inductive heating ensures, in particular, that during the second soldering process, the temperature at any location of the cooling body is kept at a constant low level in order to prevent release of the first solder connection.

Soldering of the heat exchanging means is simplified by providing the heat exchanging grooves with a soldering aid, e.g. a soldering flux and/or soldering paste, before inserting the heat exchanging means. The side of the cooling body where the heat exchanging means are to be provided may, in particular, be coated or covered with a soldering aid, such that the soldering aid gets into the heat exchanging grooves at least during insertion of the heat exchanging means into the heat exchanging grooves.

In an advantageous fashion, a second, wider depression is generated along the coolant channel groove after recessing the coolant channel groove, whose height corresponds to approximately the thickness of the cover part. The cover part may be inserted into this second, wider depression. As a result, the cover part is flush with or only slightly projects past the surface of the cooling body. This produces an almost planar surface of the cooling body, on which the components can be disposed in a simple manner. It is clear that the depression may initially be produced, e.g. as a first groove, wherein a second, narrower groove for the coolant channel can be produced in the bottom of the first groove.

The grooves are preferably milled, which permits precise manufacture of the coolant channel and the heat exchanging grooves.

Good fit of the cover part may be achieved by producing the cover part through laser cutting. The cover part may thereby consist e.g. of brass or a higher-grade material. If the cooling body consists of copper, soldering of the cover part to the cooling body is particularly facilitated. Moreover, corrosion due to coolant, in particular water, is prevented.

Mounting of components that discharge heat is advantageously supported by providing mounting aids, in particular, mounting holes in or on the cooling body, for fixing the components to the cooling body so that they will be held stationary on the cooling body.

In a preferred method variant, the surface of the cooling body is milled planar after soldering the cover part to the cooling body. This ensures that the components are supported on the cooling body on a large surface, providing optimum heat transfer from the components to the cooling body. Surface milling is required only in regions where components are mounted to the cooling plate. Surface milling is not required in regions where lamellae are provided.

In one method variant, a stack of layers, consisting of a first layer, a second layer in which the coolant channel groove is formed, and the cover part, is soldered prior to introduction of the heat exchanging grooves. In this type of production, the coolant channel groove need not be milled into the cooling body. Production of a cover part through laser cutting is not required either. The cover part may be a plate which substantially corresponds to the dimensions of the first layer. A soldering aid may be disposed between the individual layers. The first and second layers and the cover part may be pressed before soldering. Several copper parts, which form the second layer, may be disposed on the first layer to form the coolant channel, wherein the coolant channel is formed by the space between the parts. When the layers have been soldered, the heat exchanging grooves may be milled and the heat exchanging means may be soldered to the cooling body. Alternatively, the cover part or the first layer may already have cooling lamellas to simplify production.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 shows a perspective view of a cooling body with a coolant channel of a cooling device, but without heat exchanging means;

FIG. 2 shows a perspective view of the cooling body of FIG. 1 with introduced heat exchanging grooves;

FIG. 3 shows a perspective view of the cooling body of FIGS. 1, 2 after one further production step;

FIG. 4 shows a top view of part of the cooling body to illustrate a further production variant.

Like reference symbols in the various drawings indicate like elements.

### DETAILED DESCRIPTION

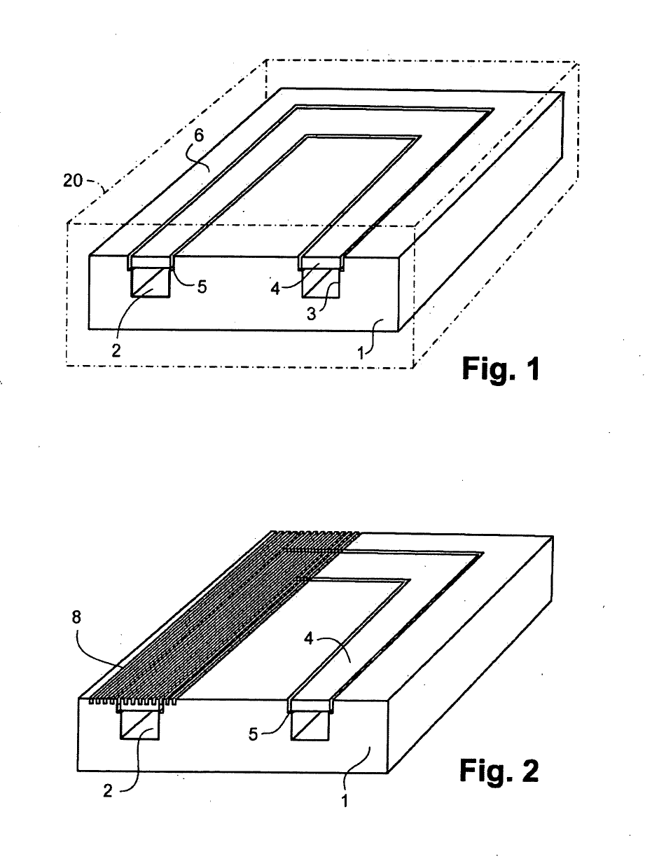

FIG. 1 shows a cooling body 1 comprising a coolant channel 2. The coolant channel 2 may be connected to an open coolant circuit, e.g. a water circuit. It is defined by a coolant channel groove 3 milled into the coolant body 1, and a cover part 4. The cover part 4 is in a depression 5 the height of which corresponds approximately to the thickness of the cover part 4 and the width of which is slightly greater than the width of the coolant channel groove 3. When the cover part 4 is inserted into the depression 5, the surface 6 of the cooling body 1 is approximately planar. The cooling body 1 preferably consists of copper and the cover part 4 of brass. The cover part 4 is soldered to the cooling body 1. When copper or higher-grade metals are used, the coolant channel 2 is corrosion-resistant. The cooling body 1 and cover part 4 are enclosed in a substantially air-tight housing 20, shown in dotted lines in FIG. 1.

A further method step for producing the cooling body 1 is shown in FIG. 2. When the cover part 4 has been soldered to the cooling body 1 at the depression 5, a plurality of heat exchanging grooves 8 are milled into the surface of the cooling body 1. Heat transfer into the coolant is particularly facilitated via the heat exchanging grooves 8, which are disposed above the coolant channel 2.

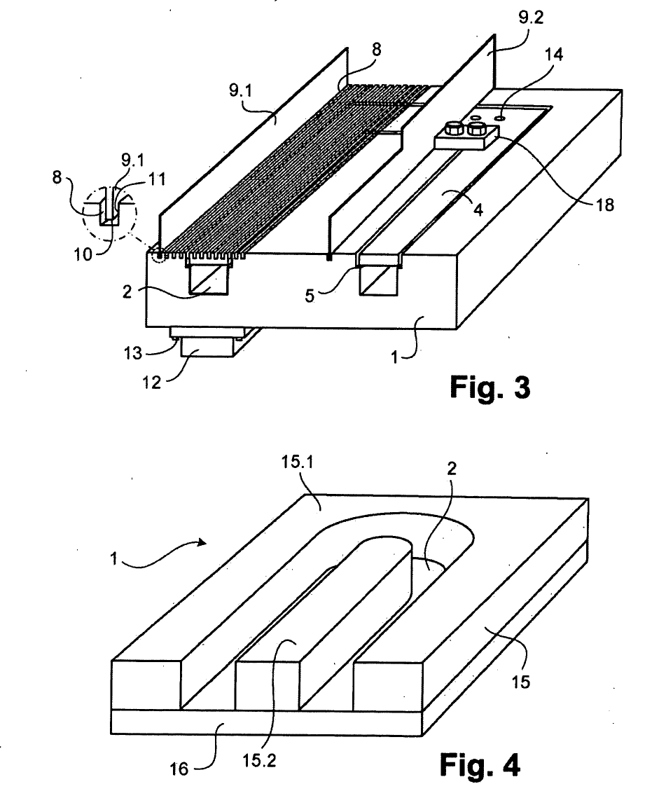

In FIG. 3, a heat exchanging means 9.1, which is exemplarily formed as a lamella, is inserted into one of the heat exchanging grooves 8, where it is soldered to the cooling body 1. Since the heat exchanging means 9.1 is inserted into the heat exchanging groove 8 to a certain degree, heat may be introduced into the cooling body 1 not only at one location of the cooling body 1 opposite to the narrow side 10 of the lamella (i.e., at the bottom of the groove 8) but also laterally, via groove sides 11.

FIG. 3 also shows that heat generating means 12 (e.g., heat generating electronic components) are provided on the opposite side of the cooling body 1, in particular, are screwed thereto using screws 13. Any other component holders may be used instead of screws, such as clamps. The heat of the heat generating means 12 is at least partially adopted by the cooling body 1. The heat generating means 12 may also dissipate heat into the surrounding air within the housing. The air is then cooled by the lamellae (heat exchanging means 9.1 and 9.2) on the opposite side of the cooling body.

The heat exchanging means 9.2 exemplarily shows that the heat exchanging means 9.2 may have different heights along their extension. In order to improve discharge of heat from the surroundings of another heat generating electronic component 18 mounted via mounting aids 14 formed as mounting holes, the heat exchanging means 9.2 has a larger height in the section adjacent the mounting aids 14. When lamellae, similar to lamella 9.2, of different heights are used, the space in the housing is optimally utilized and the lamellae can be optimally adjusted to components of different heights that are mounted in the housing but not on the cooling plate.

FIG. 4 shows a top view of a second layer 15 of the cooling body 1 which is produced in accordance with an alternative production method. The second layer 15 has parts 15.1, 15.2 which are disposed on a first layer 16. A coolant channel 2 is formed between the parts 15.1, 15.2. A cover part (not shown), which has substantially the same basic surface as the first layer 16, can be disposed on the first and second layers 15, 16. The stack of layers formed thereby can subsequently be soldered to form a cooling body 1 prior to milling the heat exchanging grooves.

A number of embodiments of the invention have been described. Nevertheless, it will be understood that various modifications may be made without departing from the spirit and scope of the invention.

For example, the heat exchanging lamellae may be disposed on both sides of the cooling body. In this case, the lamellae would preferably be disposed adjacent the heat generating components on each side. For example, referring to FIG. 3, one or more lamella(e) may be placed adjacent the heat generating means 12, similar to the positioning of heat exchanging means 9.2 relative to heat generating component 18.

Moreover, the lamellae may have any desired geometry, and may be present in any desired number.

Additionally, the heat generating means may be positioned in other areas of the electrical unit, for example on an inner wall of the housing. In this case, the heat generating means dissipate heat to the air within the housing, which is then cooled by the cooling body and the heat exchanging means mounted on the cooling body. In this case, it is generally preferred that heat exchanging means be provided on the cooling body in the vicinity of the heat generating means, for example on an area of the cooling body facing the region of the inner wall of the housing where heat generating components are mounted. Accordingly, other embodiments are within the scope of the following claims.

What is claimed is:

1. An electronic component cooling device for an electrical unit, the cooling device comprising:
a housing, enclosing a volume of air and being at least substantially sealed in an air-tight manner;
a cooling body, disposed in the housing, constructed so that a coolant may flow through the cooling body;
heat generating devices, mounted to the cooling body, so as to transfer heat to the cooling body via contact transmission; and
a heat exchanger, connected to the cooling body in a thermally conducting manner, to cool the air contained in the housing.

2. The cooling device according to claim 1, further comprising a fan disposed in the housing.

3. The cooling device according to claim 1, wherein the heat exchanger comprises heat exchanging elements.

4. The cooling device according to claim 3 wherein the heat exchanging elements comprise lamellae.

5. The cooling device according to claim 1 wherein the electrical unit comprises a power supply device.

6. The cooling device according to claim 3, characterized in that the heat exchanging elements are disposed on one side of the cooling body and the heat generating devices are disposed on the opposite side of the cooling body.

7. The cooling device according to claim 1, characterized in that the heat exchanger comprises heat exchanging elements disposed on opposite sides of the cooling body.

8. The cooling device according to claim 3, characterized in that the heat exchanging elements are positioned between the heat generating devices.

9. The cooling device according to claim 1, characterized in that a coolant channel is formed in the cooling body.

10. The cooling device according to claim 9, characterized in that the heat generating devices are mounted in mounting positions, and the coolant channel extends along the mounting positions of the heat generating devices.

11. The cooling device according to claim 1, characterized in that the heat exchanger comprises heat exchanging elements having different heights.

12. The cooling device according to claim 4, characterized in that the lamellae of the heat exchanging elements are soldered in heat exchanging grooves of the cooling body.

13. The cooling device according to claim 1, characterized in that the heat exchanger comprises several heat exchanging elements disposed parallel to each other.

14. The cooling device according to claim 1, characterized in that the cooling body is made from copper or a higher-grade metal.

15. The cooling device of claim 3, characterized in that the heat exchanging elements are made from copper or a higher-grade metal.

16. A method for producing a cooling device comprising the following method steps:
a. generating a coolant channel groove in a cooling body;
b. closing the coolant channel groove with a cover part to form a coolant channel; and
c. arranging heat exchanging elements on the cooling body.

17. The method according to claim 16, characterized in that arranging the heat exchanging elements includes recessing several heat exchanging grooves in the cooling body and inserting at least a portion of the heat exchanging elements into the heat exchanging grooves.

18. The method according to claim 16, further comprising soldering the cover part to the cooling body at a first soldering temperature, and soldering the heat exchanging elements to the cooling body at a second lower soldering temperature.

19. The method according to claim 18, characterized in that soldering is effected through inductive heating.

20. The method according to claim 17, characterized in that the heat exchanging grooves are provided with a soldering aid prior to insertion of the heat exchanging elements.

21. The method of claim 16 further comprising, after recessing the coolant channel groove, generating a second, wider depression along the coolant channel, the height of which corresponds approximately to the thickness of the cover part.

22. The method according to claim 16, characterized in that the coolant channel groove and the heat exchanging grooves are milled.

23. The method according to claim 16, characterized in that the cover part is produced by laser cutting.

24. The method according to claim 16 further comprising introducing mounting aids into the cooling body, the mounting aids being configured to allow one or more heat generating device to be mounted on the cooling body.

25. The method according to claim 18, characterized in that a surface of the cooling body is milled planar after soldering the cover part to the cooling body.

26. The method according to claim 17, characterized in that a stack of layers, consisting of a first layer, a second layer in which the coolant channel groove is formed, and the cover part, is soldered prior to recessing the heat exchanging grooves.

27. A method of cooling one or more electronic component(s) comprising:
providing a substantially air-tight housing, enclosing a volume of air,
providing a cooling body, within the housing, the cooling body being constructed so that a coolant may flow through the cooling body;
mounting one or more heat generating device(s) to the cooling body, so as to transfer heat to the cooling body via contact transmission; and
connecting a heat exchanger to the cooling body in a thermally conducting manner, to cool the air contained in the housing.

28. An electronic component cooling device comprising:
a housing, at least substantially sealed in an air-tight manner and enclosing a volume of air;
a cooling body, disposed in the housing, the cooling body being constructed so that a coolant may flow through the cooling body;
means for mounting heat generating devices to the cooling body so as to transfer heat from the heat generating devices to the cooling body via contact transmission; and
heat exchanging means for cooling the air contained in the housing, connected to the cooling body in a thermally conducting manner.
